(19) United States
(12) Patent Application Publication
(10) Pub. No.: US 2013/0093453 A1
(43) Pub. Date: Apr. 18, 2013

(54) CONNECTING DEVICE, SEMICONDUCTOR WAFER TEST APPARATUS COMPRISING SAME, AND CONNECTING METHOD

(71) Applicant: Hiroshi Sakata, Saitama (JP)

(72) Inventor: Hiroshi Sakata, Saitama (JP)

(73) Assignee: ADVANTEST CORPORATION, Tokyo (JP)

(21) Appl. No.: 13/704,301

(22) PCT Filed: Aug. 17, 2010
(86) PCT No.: PCT/JP2010/063880

§ 371 Date: Dec. 14, 2012

(51) Int. Cl. H01R 12/16; H01R 43/00; G01R 1/04

(52) U.S. Cl. CPC H01R 23/68; G01R 1/0491; H01R 43/00
USPC 324/756.03; 439/65; 29/825

(57) ABSTRACT

A connecting device electrically connects a performance board which has PB terminals and a test head, and includes a sub board which is electrically connected to the test head and has sub terminals which face the PB terminals, a sealing mechanism which forms a sealed space between the sub board and the performance board, and a pressure reducing device which reduces the pressure of the sealed space. The pressure reducing device reduces the pressure of the sealed space so that the performance board and the sub board approach each other and the PB terminals and the sub terminals contact.

### TECHNICAL FIELD

The invention relates to a connecting device which connects a circuit board and a test head which are used for testing integrated circuit devices or other devices under test which are formed on a semiconductor wafer (hereinafter also referred to representatively as “IC devices”), a semiconductor wafer test apparatus which comprises the same, and a connecting method.

### BACKGROUND ART

Known in the art is a test apparatus which brings contactors, which are electrically connected to pin electronics of the test head, into contact with a circuit board of a probe card (for example, see PLT 1).

In this test apparatus, a contactor housing of the contactors is formed with a slanted part, the circuit board is provided with a guide unit which has a roller, and the slanted part and roller are made to slide against each other so as to push the contactors against the circuit board and electrically connect the test head and the circuit board.

### CITATIONS LIST

### Patent Literature

PLT 1: Japanese Patent No. 4437508

### SUMMARY OF INVENTION

### Technical Problem

In the above invention, wear of the sliding parts of the slanted part and roller or dust from the sliding parts are liable to occur, so sometimes reliability of the electrical connection between the test head and the circuit board could not be sufficiently secured.

The technical problem of the present invention is to provide a connecting device, a semiconductor wafer test apparatus comprising the same, and a connecting method which can improve the reliability of the electrical connection between the circuit board and the test head.

### Solution to Problem

The connecting device according to the present invention is a connecting device which electrically connects a circuit board which has first terminals and a test head, characterized by comprising: a connection board which is electrically connected to the test head and has second terminals which face the first terminals; a sealing means which forms a sealed space between the connection board and the circuit board, and a pressure reducing means which reduces the pressure of the sealed space, wherein the pressure reducing means reduces the pressure of the sealed space so that the circuit board and the connection board approach each other and the first terminals and the second terminals contact (see claim 1).

In the above invention, one of the first terminal or the second terminal may have a contactor which can elastically deform along the contact direction of the first terminal and the second terminal (see claim 2).

In the above invention, the sealing means may have: a housing which has an external shape which is larger than the connection board and which is attached to an opposite side surface to a formation surface of the second terminals in the connection board; and a ring-shaped first seal member which is provided between an outside part and the circuit board, the outside part which is positioned outside from the connection board in the housing (see claim 3).

In the above invention, the sealing means may further have a ring-shaped second seal member which is provided between the housing and the connection board (see claim 4).

In the above invention, the first seal member may be attached to one of the housing or the circuit board, and the sealing means may further have a ring-shaped conductor pattern which is attached to the other of the circuit board or the housing and closely contacts the first seal member (see claim 5).

In the above invention, the first seal member may be attached to the housing, and the conductor pattern may include a metal interconnect pattern which is provided on the circuit board and is formed simultaneously with the first terminals (see claim 6).

In the above invention, the sealing means may have a ring-shaped seal member which is provided between the circuit board and the connection board (see claim 7).

In the above invention, the seal member may be attached to one of the circuit board or the connection board, and the sealing means may further comprise a ring-shaped conductor pattern which is provided on the other of the connection board or the circuit board and which closely contacts the seal member (see claim 8).

In the above invention, the seal member may be attached to the connection board, and the conductor pattern may include a metal interconnect pattern which is provided on the circuit board and is formed simultaneously with the first terminals (see claim 9).

In the above invention, one of the circuit board or the connection board may have a suction hole which opens to the sealed space, and the pressure reducing means may reduce the pressure of the sealed space through the suction hole (see claim 10).

In the above invention, one of the circuit board, the connection board, or the housing may have a suction hole which opens to the sealed space, and the pressure reducing means may reduce the pressure of the sealed space through the suction hole (see claim 11).

In the above invention, the device may further comprise a positioning means which positions the connection board relative to the circuit board (see claim 12).

In the above invention, the first terminals and the second terminals may be provided inside of the sealed space, and the positioning means may be provided outside of the sealed space (see claim 13).

A semiconductor wafer test apparatus according to the present invention is characterized by comprising: a test head; a circuit board which is electrically connected to a probe card; and the above connecting device which electrically connects the test head and the circuit board, wherein the connecting device is electrically connected to the test head through a wiring cable (see claim 14).

In the above invention, the circuit board may have the first terminals, the connecting device may have a plurality of connection boards which have second terminals which can contact the first terminals, and the semiconductor wafer test apparatus may further comprise a frame having a holding members which hold the plurality of connection boards in a freely movable manner along the contact direction of the first terminals and the second terminals (see claim 15).

In the above invention, the apparatus may further comprise a moving means which moves the connection boards through a frame relative to the circuit board along a direction substantially parallel to the main surface of the circuit board (see claim 16).

A connecting method according to present invention is a connecting method of electrically connecting a circuit board which has first terminals and a test head, characterized by comprising: a facing step of making second terminals of a connection board face the first terminals, the connection board which is electrically connected with a test head; a sealing step of forming a sealed space between the circuit board and the connection board; and a pressure reducing step of reducing the pressure of the sealed space so that the circuit board and the connection board approach each other and the first terminals and the second terminals contact (see claim 17).

In the above invention, the method may further comprise a positioning step of positioning the connection board relative to the circuit board (see claim 18).

In the above invention, the method may further comprise a moving step of moving the connection board relative to the circuit board along a direction substantially parallel to the main surface of the circuit board (see claim 19).

### Advantageous Effects of Invention

In the present invention, a pressure of a sealed space which is formed between a connection board, which is electrically connected to the test head, and a circuit board is reduced so that the circuit board and the connection board approach each other and the first terminal and the second terminal contact, so the reliability of the electrical connection between the test head and the circuit board can be improved.

### BRIEF DESCRIPTION OF DRAWINGS

FIG. 1 is a view which shows a semiconductor wafer test apparatus in a first embodiment of the present invention.

FIG. 2 is a cross-sectional view of a connecting device and a performance board in the first embodiment of the present invention.

FIG. 3 is an enlarged cross-sectional view of a part III in FIG. 2.

FIG. 4 is a perspective view which shows a contactor in the first embodiment of the present invention.

FIG. 5 is a perspective view which shows a performance board and a connecting device in the first embodiment of the present invention.

FIG. 6 is a cross-sectional view which shows a first modification of a connecting device in the first embodiment of the present invention.

FIG. 7 is a cross-sectional view which shows a second modification of a connecting device in the first embodiment of the present invention.

FIG. 8 is a cross-sectional view which shows a third modification of a connecting device in the first embodiment of the present invention.

FIG. 9 is a cross-sectional view which shows a fourth modification of a connecting device in the first embodiment of the present invention.

FIG. 10 is a cross-sectional view which shows a fifth modification of a connecting device in the first embodiment of the present invention.

FIG. 11 is a plan view which shows a sixth modification of a connecting device in the first embodiment of the present invention.

FIG. 12 is a flow chart which shows a connecting method in the first embodiment of the present invention.

FIG. 13 is a cross-sectional view which explains a sealing step of FIG. 12.

FIG. 14 is a cross-sectional view which shows a modification of the sealing step of FIG. 12.

FIG. 15 is a cross-sectional view which explains a pressure reducing step of FIG. 12.

FIG. 16 is an overall cross-sectional view which explains a moving step of FIG. 12.

FIG. 17 is a cross-sectional view which shows a connecting device in the second embodiment of the present invention.

FIG. 18 is a cross-sectional view which shows a first modification of a connecting device in the second embodiment of the present invention.

FIG. 19 is a cross-sectional view which shows a second modification of a connecting device in the second embodiment of the present invention.

FIG. 20 is a cross-sectional view which shows a third modification of a connecting device in the second embodiment of the present invention.

FIG. 21 is a view which shows a semiconductor wafer test apparatus in a third embodiment of the present invention.

FIG. 22 is an enlarged view of a part XXII of FIG. 21.

FIG. 23 is a flow chart which shows a connecting method of the third embodiment of the present invention.

FIG. 24 is a cross-sectional view which explains a sealing step of FIG. 23.

FIG. 25 is a cross-sectional view which explains a pressure reducing step of FIG. 23.

### DESCRIPTION OF EMBODIMENTS

Below, embodiments of the present invention will be explained based on the drawings.

### First Embodiment

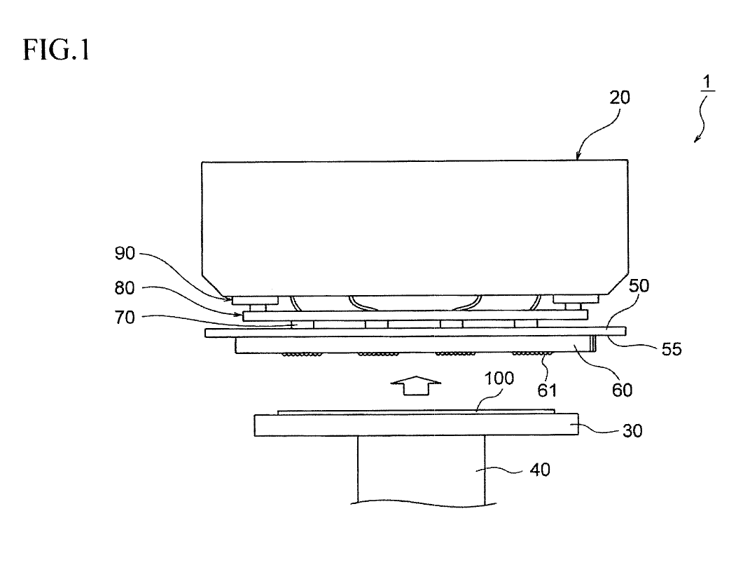

FIG. 1 is a view which shows a semiconductor wafer test apparatus in the present embodiment.

The semiconductor wafer test apparatus 1 (electronic device test apparatus) in the present embodiment is an apparatus which tests IC devices which are formed on a semiconductor wafer 100. As shown in FIG. 1, it comprises a test head 20, a wafer tray 30, a conveyor device 40, a performance board 50, a probe card 60, a connecting device 70, a frame 80, and a connection moving device 90. Note that, the performance board 50 is equivalent to one example of the circuit board of the present invention.

This semiconductor wafer test apparatus 1, when testing IC devices, makes a semiconductor wafer 100 which is held by suction on a wafer tray 30 face the probe card 60. From that state, the conveyor device 40 is used to make the wafer tray 30 further rise. Due to this, the semiconductor wafer 100 is pushed against the bumps 61 of the probe card 60. Further, the test head 20 inputs and outputs test signals to and from the IC devices through the connecting device 70, the performance board 50, and the probe card 60 so as to test the IC devices. Note that, a system other than a pressing system (for example, a pressure reducing system) may also be used to make the semiconductor wafer 100 and the probe card 60 contact each other.

The conveyor device 40 can move and rotate the wafer tray 30 which holds the semiconductor wafer 100 in three dimensions and move the semiconductor wafer 100 to a position which faces the probe card 60.

The probe card 60 comprises a membrane board which has bumps 61, a pitch conversion board (not shown), or other board which are overlaid each other and is electrically connected with the performance board 50. The bumps 61 are arranged so as to correspond to pads of the IC devices of the semiconductor wafer 100 and function as contactors for the semiconductor wafer 100. Note that, the probe card is not particularly limited to the above-mentioned configuration. Further, the contactors may also be cantilever type probe pins or pogo pins etc.

In the present embodiment, when the conveyor device 40 is used to push the semiconductor wafer 100 against the bumps 61 of the probe card 60, the probe card 60 and the semiconductor wafer 100 are electrically connected and the electrical connections between the boards inside the probe card 60 are also secured.

Here, the number of tester channels (maximum number of test pins) of the test head 20 in the present embodiment is, for example, 5000 or so. Compared with the number of PB terminals 52 of the performance board 50 explained later (10,000 or so), this is about half.

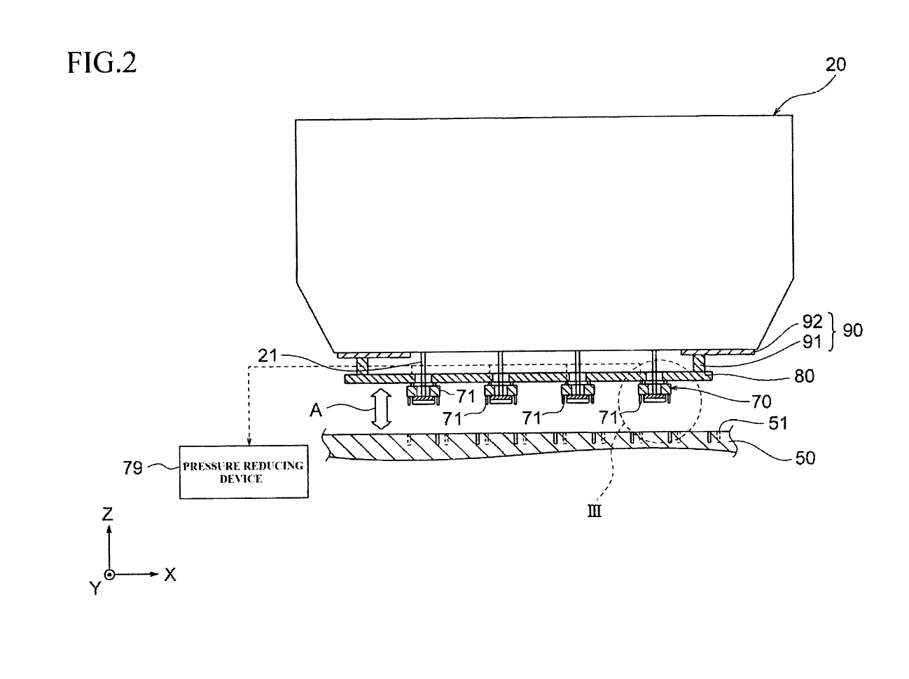

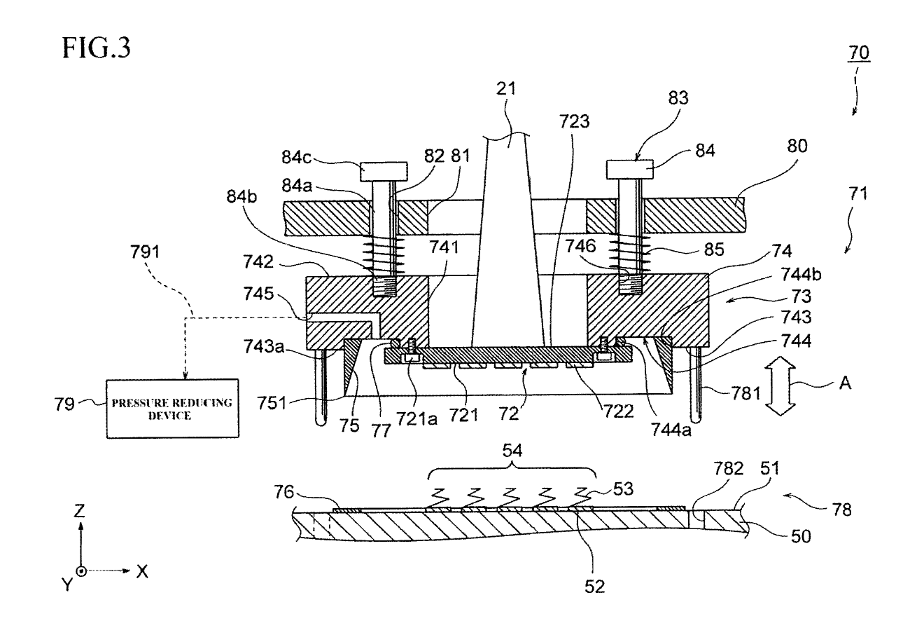

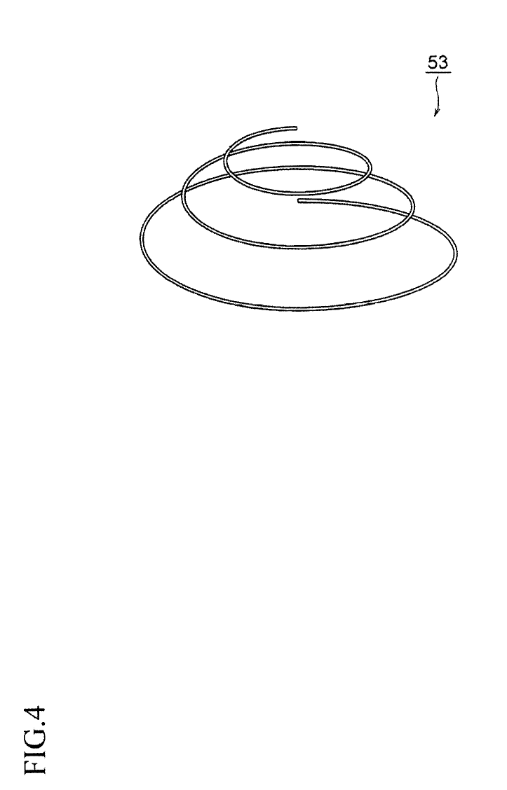

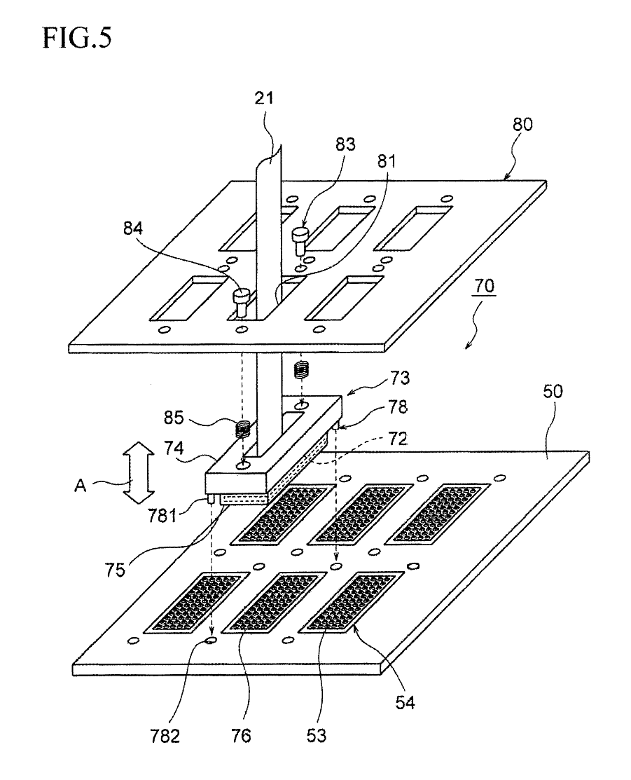

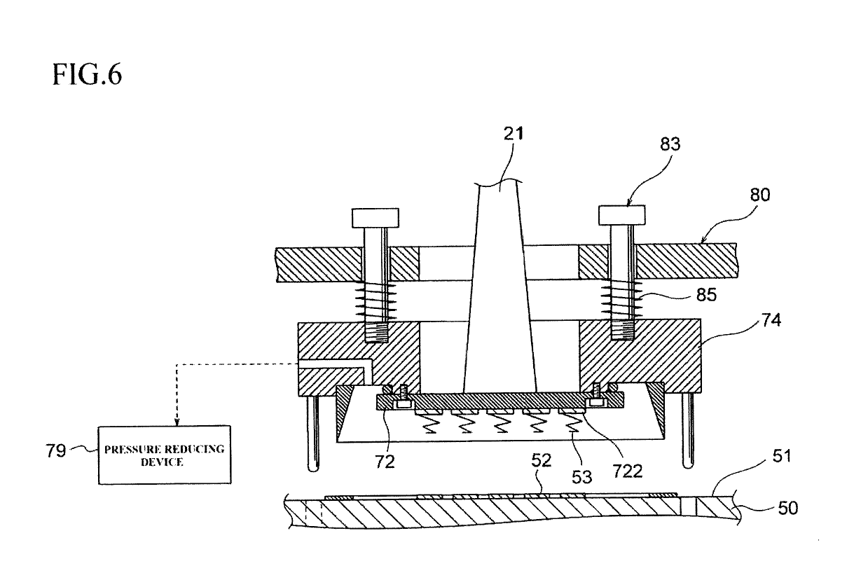

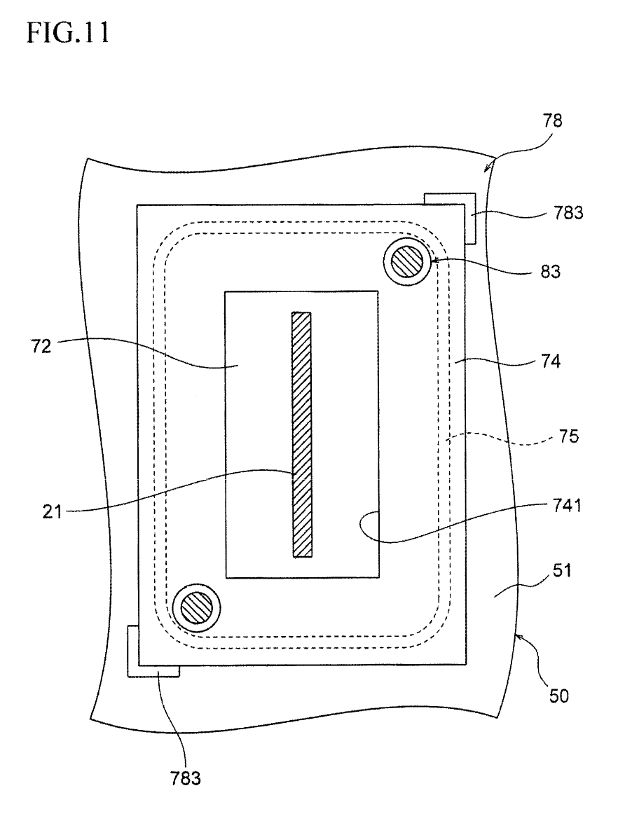

FIG. 2 is a cross-sectional view of a connecting device and a performance board in the present embodiment, FIG. 3 is an enlarged cross-sectional view of a part III in FIG. 2, FIG. 4 is a perspective view which shows a contactor in the present embodiment, FIG. 5 is a perspective view which shows a performance board and a connecting device in the present embodiment, FIG. 6 to FIG. 10 are cross-sectional views which show modifications of a connecting device in the present embodiment, and FIG. 11 is a plan view which shows a modification of a connecting device in the present embodiment.

The performance board 50 is a substantially rectangular shaped board which is electrically connected through the probe card 60 to the semiconductor wafer 100 and is electrically connected through the connecting device 70 to the test head 20. As specific examples of the performance board 50, a rigid board which is composed of glass epoxy resin or other synthetic resin material may be illustrated.

The top surface 51 of the performance board 50, as shown in FIG. 3, is provided with PB terminals 52 which form electrical contacts with the sub terminals 722 of the sub board 72 (explained later). The PB terminals 52 are electrically connected with bumps 61 (see FIG. 1) through not particularly shown wiring inside the performance board 50 and the board inside the probe card 60. The PB terminals 52 can, for example, be formed by plating the top surface 51, printing conductive paste, etching, etc. Note that, the PB terminals 52 is equivalent to one example of the first terminals of the present invention.

In the present embodiment, as shown in FIG. 3 and FIG. 5, a plurality of PB terminals 52 form a PB terminal group 54. The top surface 51 of the performance board 50 is provided with a plurality of such PB terminal groups 54. Note that, the top surface 51 of the performance board 50 in the present embodiment is provided overall with about 10,000 PB terminals 52.

Further, as shown in FIG. 3 and FIG. 5, in the present embodiment, these PB terminals 52 have contactors 53 attached to them. The contactors 53, as shown in FIG. 4, are conically shaped spring coils which are composed of materials which have conductivity and can elastically deform along the contact direction A (shown by arrow mark in FIG. 3) with the sub terminals 722 of the sub board 72. The contactors 53 are, for example, fastened to the PB terminals 52 by soldering. Note that, as specific examples of such contactors 53, for example, Spiral Contacts® may be illustrated.

Further, the contactors 53 need only be able to elastically deform along the contact direction A and to have conductivity. They are not limited to the above-mentioned spring coils. For example, the contactors may also be plate springs which have conductivity.

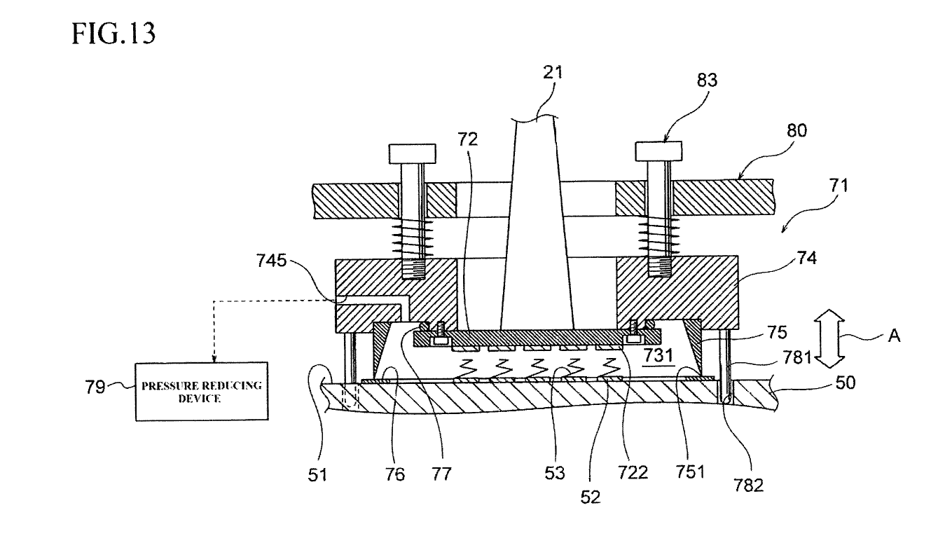

The connecting device 70, as shown in FIG. 2, is a device which electrically connects the test head 20 and the performance board 50. The connecting device 70 has: connection units 71 which are electrically connected to the test head 20 through wiring cables 21; and a pressure reducing device 79 which reduces the pressure of sealed spaces 731 which are formed between the connection units 71 and the performance board 50 (see FIG. 13). Note that, the pressure reducing device 79 is equivalent to one example of the pressure reducing means of the present invention. Further, in the present embodiment, the connecting device 70 has a plurality of connection units 71, but the invention is not particularly limited to this.

Each connection unit 71, as shown in FIG. 3 and FIG. 5, has a sub board 72, sealing mechanism 73, and positioning mechanism 78. Note that, the sub board 72 is equivalent to one example of the connection board of the present invention, the sealing mechanism 73 is equivalent to one example of the sealing means of the present invention, and the positioning mechanism 78 is equivalent to one example of the positioning means of the present invention. Further, in FIG. 5, for convenience, only one connection unit 71 is illustrated. The illustration of the other connection units is omitted.

The sub board 72, as shown in FIG. 3 and FIG. 5, is a rectangular shaped circuit board and is fastened by bolts 721a to the bottom surface 743 of the housing 74 (explained later). Note that, the method of fastening the sub board 72 and the housing 74 is not particularly limited to this. Further, the sub terminal 722 is equivalent to one example of the second terminals of the present invention.

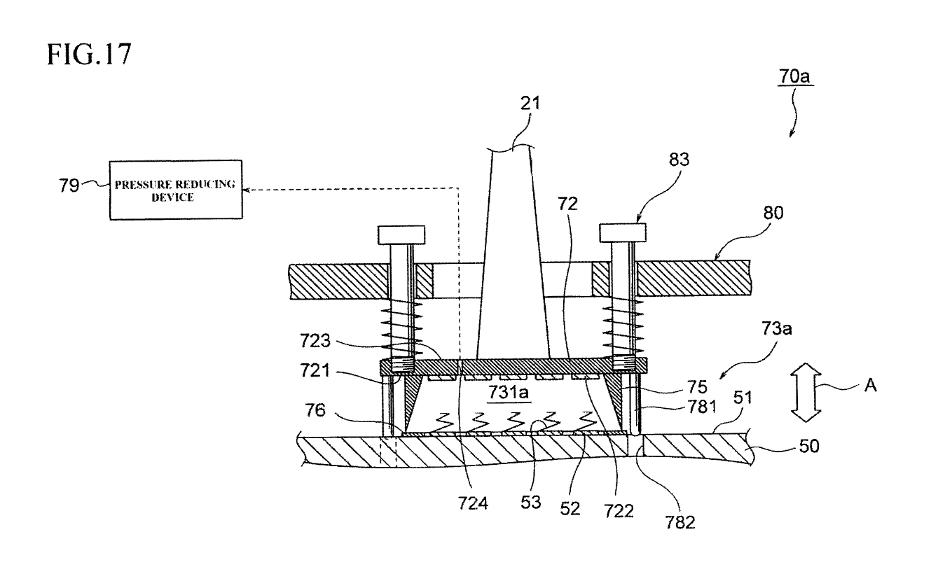

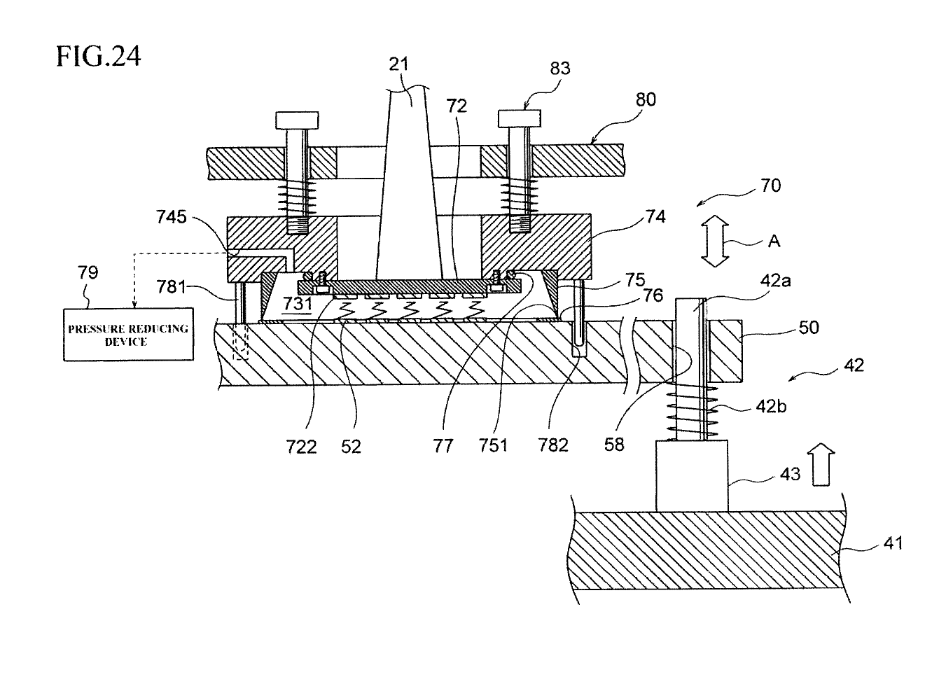

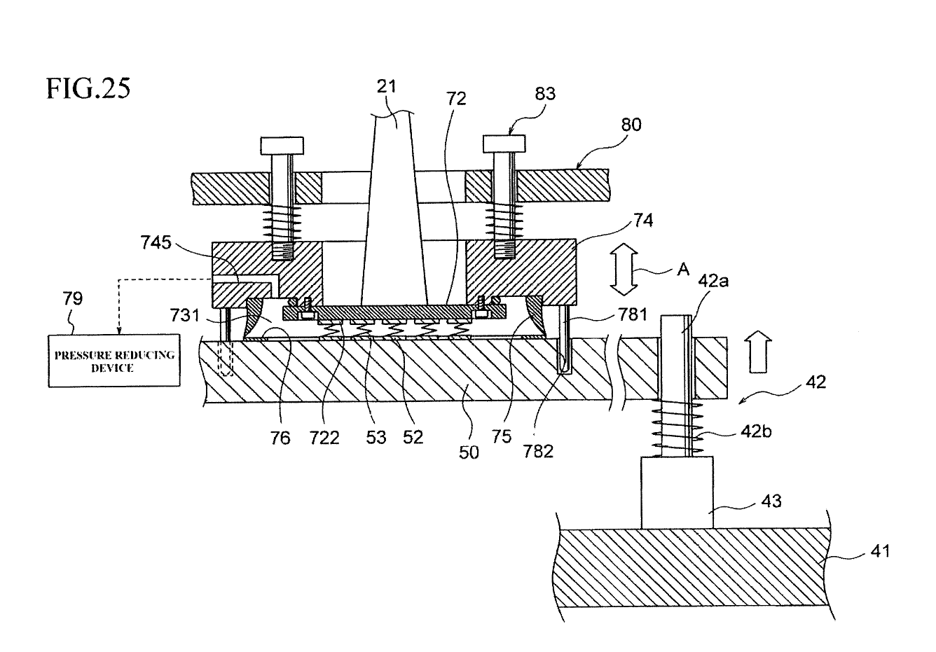

This sub board 72, as shown in FIG. 3, is connected at the top surface 723 with a wiring cable 21 of the test head 20. On the other hand, at the bottom surface 721 of the sub board 72, a plurality of sub terminals 722 which serve as electrical contacts with the PB terminals 52 of the performance board 50 are arranged. Note that, in FIG. 3, for convenience, five each of the PB terminals 52 and sub terminals 722 are shown, but the numbers of the PB terminals 52 and sub terminals 722 are not particularly limited (same in FIG. 6 to FIG. 10, FIG. 13 to FIG. 15, FIG. 17 to FIG. 20, FIG. 24, and FIG. 25).

The sub terminals 722 are electrically connected with the wiring cable 21 through interconnects (not shown) which are provided in the sub board 72. The sub terminals 722, for example, can be formed by plating the bottom surface 721 of the sub board 72, printing conductive paste, etching, etc. Note that, the bottom surface 721 of the sub board 72 is equivalent to one example of the formation surface of the present invention.

Here, in the present embodiment, as explained above, the performance board 50 is provided with contactors 53, but the invention is not particularly limited to this. As shown in FIG. 6, the sub terminals 722 may also have contactors 53 attached to them.

The sealing mechanism 73 is a mechanism which forms a sealed space 731 (see FIG. 13) between the performance board 50 and the sub board 72. As shown in FIG. 3 and FIG. 5, it has a housing 74, first seal member 75, sealing pattern 76, and second seal member 77. Note that, the sealing pattern 76 is equivalent to one example of conductor pattern of the present invention. Further, the provision or non provision of the sealing pattern or the second seal member is not particularly limited.

The housing 74 is a block shaped member which has an outer shape larger than the sub board 72 and is attached to the top surface 723 of the sub board 72. At the center part of this housing 74, a through hole 741 which passes the wiring cable 21 is formed from the top surface 742 to the bottom surface 743.

Further, the bottom surface 743 of the housing 74 is formed with a ring-shaped groove along the outer edge of the sub board 72. This groove 744 has a large width so that its inner edge part 744a is positioned on the sub board 72 and its outer edge part 744b is positioned outside from the sub board 72.

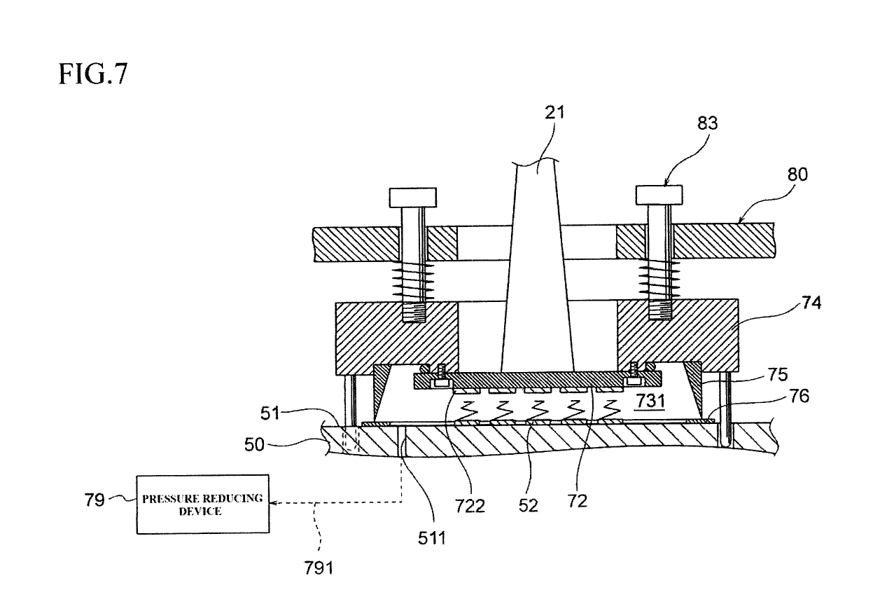

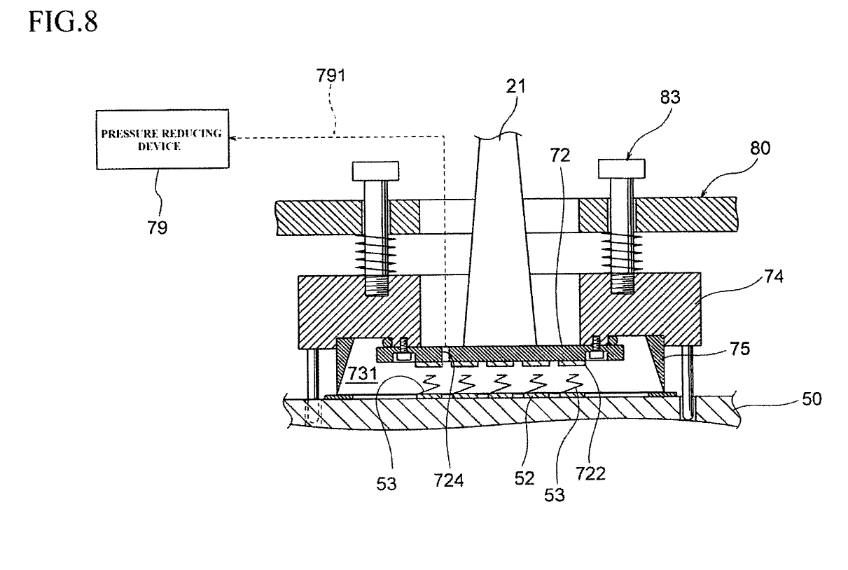

The housing 74 in the present embodiment is formed with a suction hole 745 which opens between the first seal member 75 and the second seal member 77 (sealed space 731). This suction hole 745 is connected with the pressure reducing device 79 through a suction channel 791. Note that, this suction hole 745 need only be opened to the sealed space 731 and is not limited to being formed in the housing 74. For example, as shown in FIG. 7, the performance board 50 may be formed with a suction hole 511 which opens to the sealed space 731. Alternatively, as shown in FIG. 8, the sub board 72 may be formed with a suction hole 724 which opens to the sealed space 731.

The first seal member 75, as shown in FIG. 3, is a member which seals the performance board 50 and the housing 74 in a ring shape. The first seal member 75 in the present embodiment has a ring shape (band shape). When the front end 751 (bottom end in the figure) of this ring-shaped first seal member 75 closely contacts the sealing pattern 76 on the performance board 50, a sealed space 731 (see FIG. 13) is formed. The first seal member 75 is, for example, composed of rubber or silicone rubber or other such material which can elastically deform and which is superior in sealing ability.

This first seal member 75 is attached in a ring shape on the bottom surface 743 of the housing 74 along the outside part 743a which is positioned at the outside from the sub board 72 (in the present embodiment, the outer edge part 744b of the groove 744) so as to surround the sub board 72.

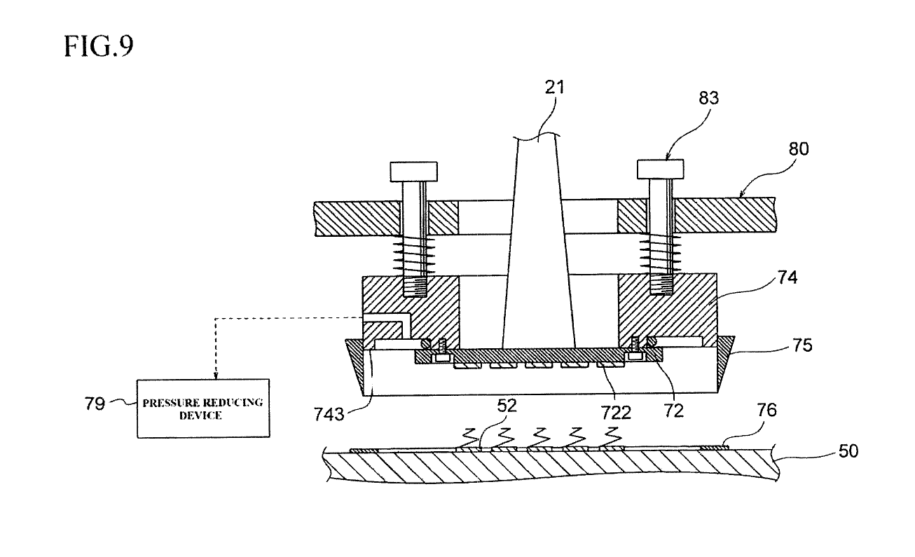

Note that, the first seal member 75 may be arranged between the performance board 50 and the housing 74 and is not limited to be attached to the groove 744 (bottom surface 743) of the housing 74. For example, as shown in FIG. 9, the first seal member 75 may also be attached along a side face of the housing 74 so as to surround the sub board 72. Note that, in that figure, illustration of the positioning mechanism (guide pins and the guide holes) is omitted.

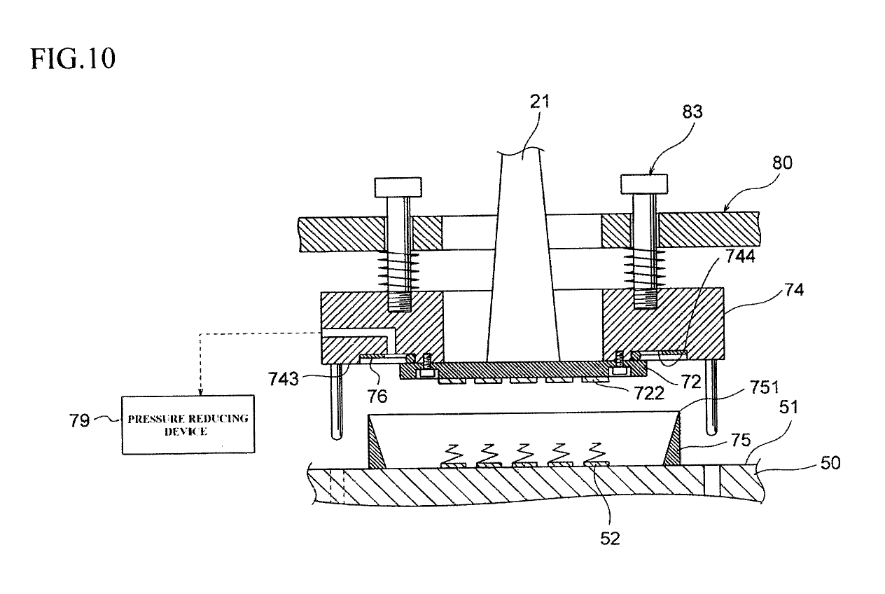

Further, as shown in FIG. 10, the first seal member 75 may be attached to the top surface 51 of the performance board 50 and the front end 751 (top end in the figure) of the first seal member 75 may be made to closely contact the housing 74. In this case, the bottom surface of the groove 744 of the housing 74 (the bottom surface 743 of the housing 74) is provided with the sealing pattern 76.

The sealing pattern 76, as shown in FIG. 3, is a ring-shaped conductor pattern which is provided on the performance board 50 so as to correspond to the first seal member 75. This sealing pattern 76 is flatter than other parts in the top surface 51 of the performance board 50. Due to this, the sealing of the sealed space 731 is improved.

This sealing pattern 76 may be an interconnect pattern made of metal which can be formed substantially simultaneously with the PB terminals 52. Due to this, it is possible to improve the sealing of the sealed space 731 by a relatively low cost. Note that, as a specific example of the metal which forms the sealing pattern 76, gold may be illustrated.

The second seal member 77, as shown in FIG. 3, is a member which seals the sub board 72 and the housing 74 in a ring shape and is attached along the inside edge part 744a of the groove 744 of the housing 74. As a specific example of this ring-shaped second seal member 77, for example, an 0-ring or packing may be illustrated.

The positioning mechanism 78, as shown in the same figure, is a mechanism which positions the sub board 72 relative to the performance board 50 through the housing 74.

This positioning mechanism 78 has: guide pins 781 which are attached to the housing 74; and guide holes 782 which are formed in the performance board 50 at positions which correspond to the guide pins 781. In the present embodiment, the guide pins 781 are inserted into the guide holes 782 so as to position the sub board 72 relative to the performance board 50.

Further, in the present embodiment, the guide pins 781 are arranged at the outside from the ring-shaped first seal member 75, while the guide holes 782 are also arranged at the outside from the ring-shaped sealing pattern 76. For this reason, in a state where the sealed space 731 is formed, the guide pins 781 and the guide holes 782 are positioned at the outside of the sealed space 731.

Note that, the method of positioning the sub board 72 with respect to the performance board 50 is not limited to the above-mentioned one which relies on guide pins and guide holes. For example, as shown in FIG. 11, it is also possible to provide the top surface 51 of the performance board 50 with ribs 783 partially along the outer edge of the housing 74 and position the sub board 72 through the housing 74.

The pressure reducing device 79, as shown in FIG. 3, is a device which reduces the pressure in the sealed space 731 (see FIG. 13) through a suction hole 745 which is formed in the housing 74. In the present embodiment, the pressure reducing device 79 reduces the pressure inside the sealed space 731 so as to make the sub board 72 approach the performance board 50 and contact the sub terminals 722 and PB terminals 52 through the contactors 53.

The frame 80, as shown in FIG. 3 and FIG. 5, is a plate-shaped member to which holding members 83 which hold a plurality of connection units 71 in a freely movable manner are attached. Parts of this frame 80 which correspond to the connection units 71 are formed with through holes 81 through which wiring cables 21 are passed. Note that, the number of connection units 71 which the frame 80 holds is not particularly limited to this. Even one is possible.

Each holding member 83 has: a pin-shaped guide member 84 which guides the connection unit 71 along the contact direction A of the above-mentioned sub terminals 722 and PB terminals 52; and a spring 85 which connects the connection unit 71 and the frame 80 along the contact direction A in a freely movable manner. In the present embodiment, a single connection unit 71 has two holding member 83 attached to the frame 80, but the number of holding members 83 is not particularly limited.

The guide member 84 has a guide part 84a, a fastening part 84b, and a stopper 84c. The guide part 84a is the body part of the guide member 84 and is inserted slidably into a guide through hole 82 which is formed in the frame 80. This guide member 84 and guide through hole 82 guide the connection unit 71 in the contact direction A and restrict movement of the connection unit 71 in the planar direction (XY direction in the figure) relative to the frame 80.

The fastening part 84b is positioned at the bottom end of the guide member 84 and is formed with a thread. In the present embodiment, that thread is engaged with a screw hole 746 which is formed in the top surface of the housing 74 so as to fasten the guide member 84 to the housing 74.

The stopper 84c has an outside shape which is larger than the guide through hole 82 of the frame 80 and is positioned at the top end of the guide part 84a. This stopper 84c contacts with the top surface of the frame 80 whereby the lower limit of the connection unit 71 is restricted.

The connection moving device 90, as shown in FIG. 2, is a device which moves the connection unit 71 via the frame 80. This connection moving device 90 has a Z-axis moving device 91 and a parallel movement device 92. Note that, the parallel movement device 92 is equivalent to one example of the moving device of the present invention.

The Z-axis moving device 91 is a device which moves the connection unit 71 relative to the performance board 50 along the contact direction A (Z-direction in the figure) so as to approach or move away from the performance board 50. This Z-axis moving device 91 is connected to the frame 80 at its bottom end and is connected with the parallel movement device 92 at its top end. As a specific example of such a Z-axis moving device 91, for example, an air cylinder or other actuator may be illustrated, but the invention is not particularly limited to this.

The parallel movement device 92 is a device which moves the connection unit 71 relative to the performance board 50 along a direction substantially parallel to the top surface 51 of the performance board 50 and is attached to the bottom of the test head 20. As a specific example of such a parallel movement device 92, for example, a feed device which comprises a motor, ball screw, etc. may be illustrated, but the invention is not limited to this.

Next, the connecting method of the test head 20 and the performance board 50 in the present embodiment will be explained.

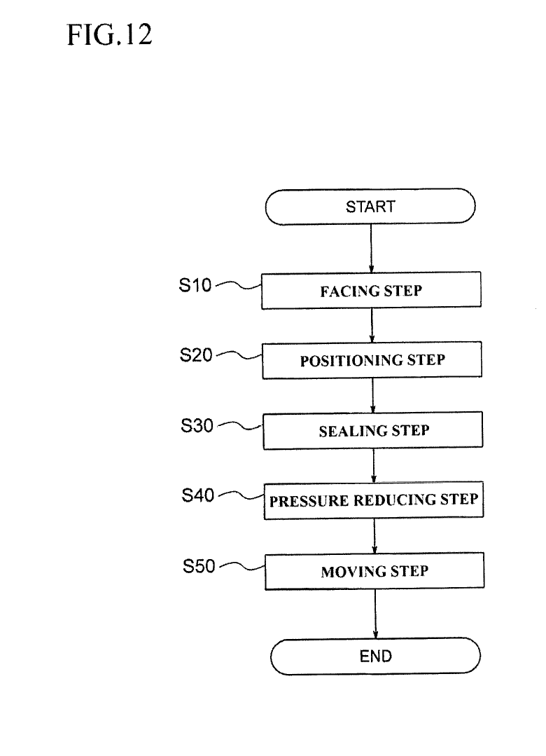

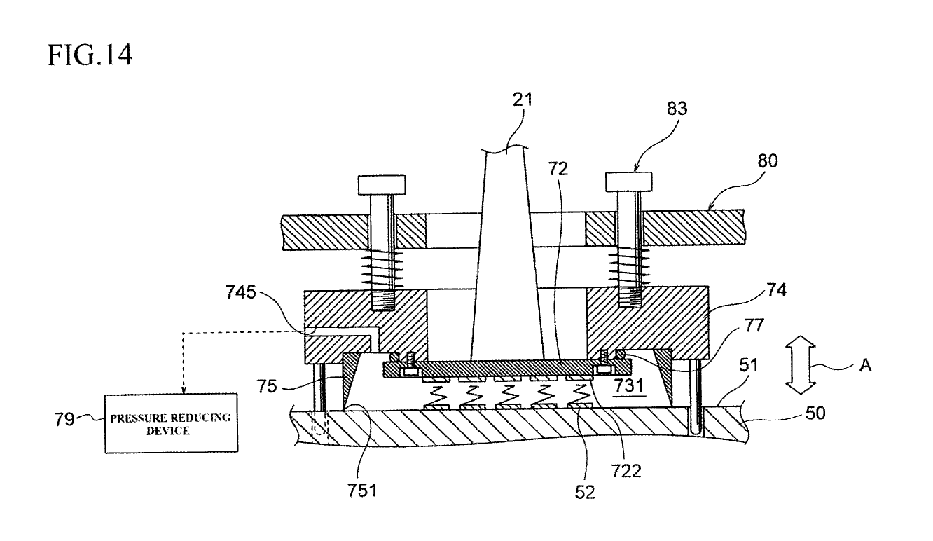

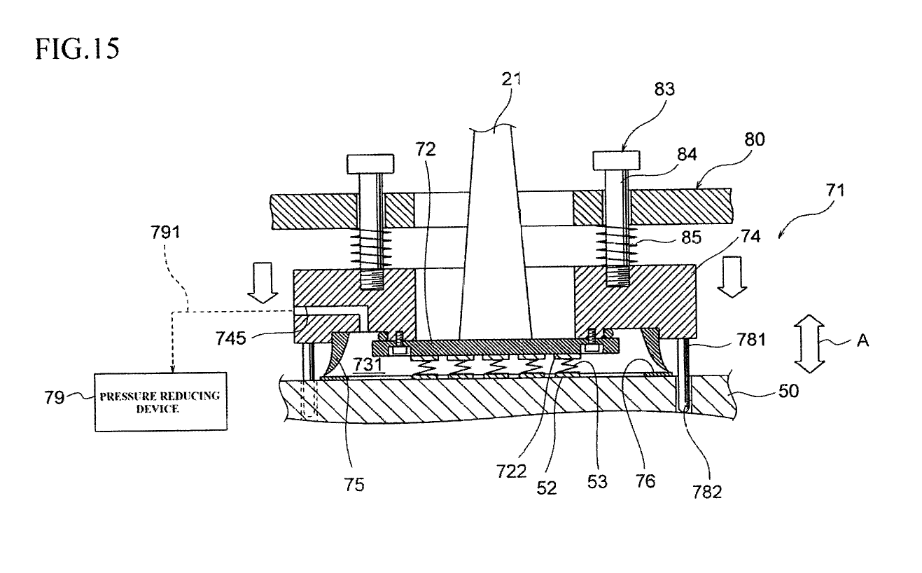

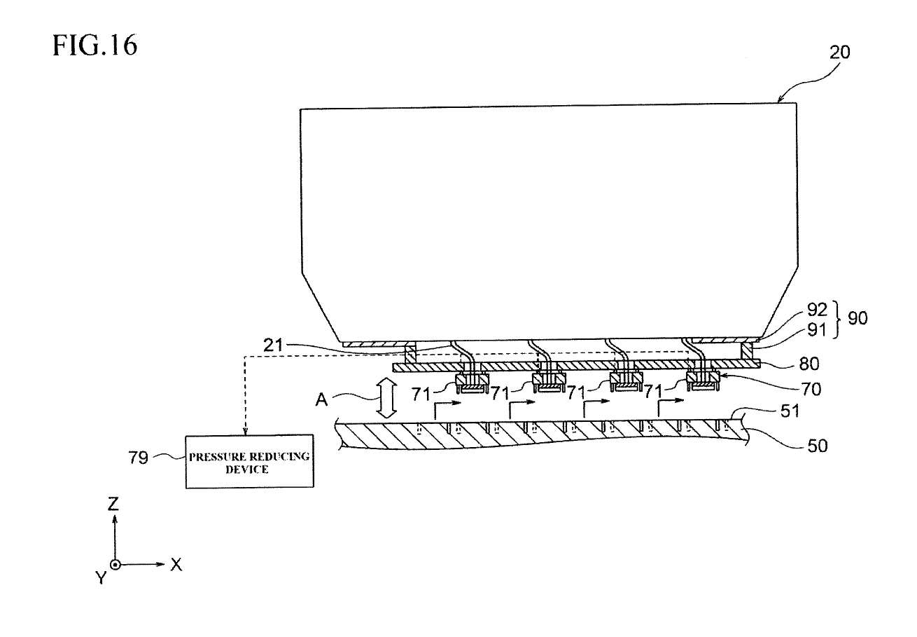

FIG. 12 is a flow chart which shows a connecting method in the present embodiment, FIG. 13 is a cross-sectional view which explains a sealing step of FIG. 12, FIG. 14 is a cross-sectional view which shows a modification of the sealing step of FIG. 12, FIG. 15 is a cross-sectional view which explains a pressure reducing step of FIG. 12, and FIG. 16 is an overall cross-sectional view which explains a moving step of FIG. 12.

The connecting method in the present embodiment, as shown in FIG. 12, comprises a facing step S10, a positioning step S20, a sealing step S30, a pressure reducing step S40, and a moving step S50.

In the facing step S10, the parallel movement device 92 is used to move the connection unit 71 above the PB terminal groups 54 of the performance board 50 and make the sub terminals 722 of the sub board 72 face the PB terminals 52.

Next, in the positioning step S20, the Z-axis moving device 91 of the connection moving device 90 is used to move the connection unit 71 downward and insert the guide pins 781 into the guide holes 782. Due to this, the sub board 72 is positioned relative to the performance board 50, whereby miscontact of the sub terminals 722 and contactors 53 is suppressed in the pressure reducing step S40.

Next, in the sealing step S30, as shown in FIG. 13, the connection unit 71 is moved further downward and the first seal member 75 is made to closely contact the sealing pattern 76 on the performance board 50. Due to this, a sealed space 731 which is defined by the performance board 50, the sub board 72, the housing 74, the first seal member 75, the sealing pattern 76, and the second seal member 77 is formed.

Note that, when no sealing pattern is provided, as shown in FIG. 14, the first seal member 75 may be made to directly contact the top surface 51 of the performance board 50 so as to form the sealed space 731 which is defined by the performance board 50, the sub board 72, the housing 74, the first seal member 75, and the second seal member 77.

Here, in the present embodiment, the holding member 83 holds the connection unit 71 in a floating state along the contact direction A, so the connection unit 71 can be further moved along the contact direction A (can be moved further downward).

Next, in the pressure reducing step S40, as shown in FIG. 15, the pressure reducing device 79 is used to reduce the pressure inside the sealed space 731 through the suction hole 745. When reducing the pressure inside the sealed space 731, a difference in air pressure is generated between the sealed space 731 and the outside air (atmospheric pressure), the housing 74 and the sub board 72 are pressed together, the springs 85 of the holding members 83 extend, the first seal member 75 closely contacts the sealing pattern 76 while deforming, and the connection unit 71 moves further downward.

By moving the connection unit 71 further downward, as shown in the figure, the sub board 72 approaches the performance board 50 and the sub terminals 722 contact the PB terminals 52 through the contactors 53. Due to this, the test head 20 and the performance board 50 are electrically connected through the connecting device 70 and the IC devices which are formed on the semiconductor wafer 100 can be tested.

Here, in the present embodiment, the number of PB terminals 52 of the performance board 50 is about 10,000, while the number of tester channels of the test head 20 is about 5000. That is, in the present embodiment, the test head 20 and the performance board 50 have to be electrically connected a plurality of times.

Therefore, in the present embodiment, in the moving step S50, as shown in FIG. 16, the connection unit 71 is moved above a PB terminal group (see FIG. 5) which is not electrically connected to the test head 20.

Specifically, first, the pressure reduction by the pressure reducing device 79 is stopped and a not particularly shown release valve is used to release the reduced pressure state of the sealed space 731. Next, as shown in FIG. 16, the Z-axis moving device 91 is used to move the connection unit 71 upward. Next, the parallel movement device 92 is used to move the connection unit 71 relative to the performance board 50 along a direction (X-direction in the figure) substantially parallel to the top surface 51 of the performance board 50.

After the end of the moving step S50, the above-mentioned steps S10 to S40 are again performed, whereby the test head 20 and the performance board 50 are again electrically connected and IC devices which are untested on the semiconductor wafer 100 can be tested.

Note that, if the number of tester channels of the test head 20 is more than the number of the PB terminals 52 of the performance board 50, the above-mentioned moving step S50 need not be performed and the connection moving device further need not have the parallel movement device.

Here, instead of the above-mentioned sealing step S30 and pressure reducing step S40, if using a cam mechanism to pull the sub board toward the performance board, the sliding action of the cam follower and the cam grooves is liable to cause wear between the members and the production of dust due to that wear.

As opposed to this, in the present embodiment, a sealed space 731 is formed between the performance board 50 and the sub board 72 and that sealed space 731 is reduced in pressure, whereby the sub board 72 is moved relatively toward the performance board 50, and the sub terminals 722 and the PB terminals 52 are made to contact. That is, sliding is not required for the operation for making the sub board 72 approach the performance board 50, so wear between the members and production of dust due to sliding can be suppressed.

Due to this, the connection state of the connecting device 70 and the performance board 50 can be stabilized and, consequently, the reliability of the electrical connection between of the test head 20 and the performance board 50 can be improved.

Further, in the present embodiment, the guide pins 781 and the guide holes 782 are arranged outside of the sealed space 731. For this reason, even if sliding of the guide pins 781 and the guide holes 782 causes the production of dust, it becomes difficult for that dust to enter between the sub terminals 722 and the PB terminals 52 which are positioned inside of the sealed space 731. Due to this, the reliability of the electrical connection between the test head 20 and the performance board 50 can be improved.

Further, even if using a cam mechanism to pull the sub board to the performance board, a strong rigidity stiffener which is specially processed to be able to withstand that pulling force has to be used to reinforce the performance board. Further, when reducing the pressure inside the probe card so as to promote electrical conduction between the boards inside the probe card, the performance board cannot be formed with through holes, so the structure for fastening such a stiffener to the performance board also easily becomes complicated.

As opposed to this, in the present embodiment, such reinforcement is not required, but compared with the case of using a cam mechanism, the structure of the performance board or connecting device can be simplified and the cost can be lowered. Further, there is no need to arrange a stiffener on the performance board, so the top surface of the performance board can be formed with more interconnects.

Further, in the present embodiment, elastically deformable contactors 53 are interposed between the sub terminals 722 and the PB terminals 52, so the contact pressure which is required for conduction between the sub terminals 722 and the PB terminals 52 is relatively low (for example, about 5 [gram per pin]).

In the present embodiment, a relatively low contact pressure obtained by reduction of the pressure is used to make the sub terminals 722 and the PB terminals 52 contact, so it is possible to suppress flexure of the performance board 50 at the time of connection of the two. Further, the performance board 50 in the present embodiment is subjected to pressure at only the parts where the sealed spaces 731 are formed, so the parts of the performance board 50 which easily flex also become narrower. Due to this, the connection state of the connecting device 70 and the performance board 50 can be stabilized and, consequently, the reliability of the electrical connection between the test head 20 and the performance board 50 can be improved.

Next, a second embodiment will be explained.

### Second Embodiment

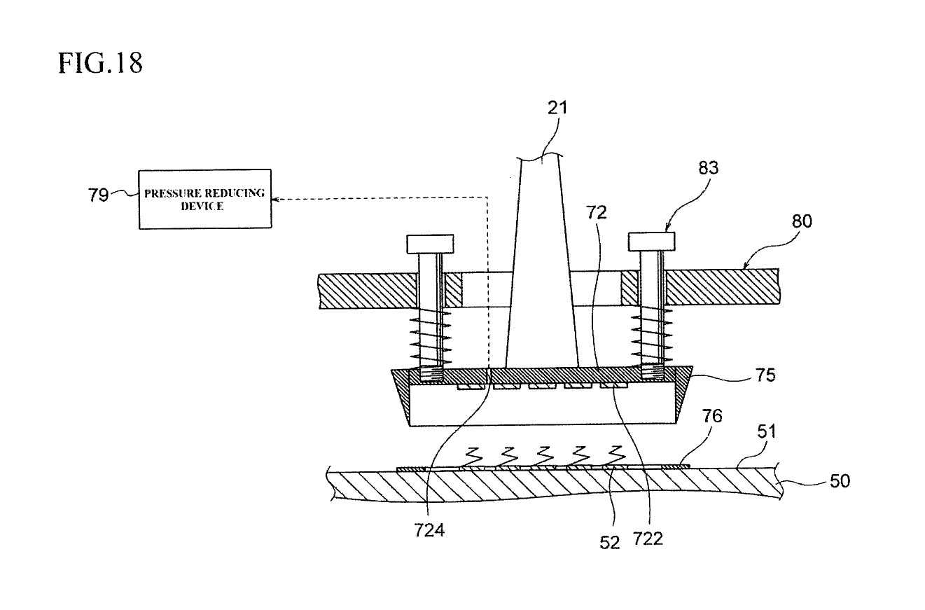

FIG. 17 is a cross-sectional view which shows a connecting device in the present embodiment, while FIG. 18 to FIG. 20 are cross-sectional views which show modifications of a connecting device in the present embodiment.

The connecting device 70a in the present embodiment differs from the first embodiment in the points of not being provided with the housing and second seal member, but the rest of the configuration is similar to the first embodiment. Below, only the points of difference from the first embodiment will be explained. Parts of the configuration which are similar to the first embodiment will be assigned the same reference numerals and explanations will be omitted.

The sealing mechanism 73a in the present embodiment, as shown in FIG. 17, comprises a first seal member 75 and a sealing pattern 76. Note that, provision or not provision of the sealing pattern, in the same way as the first embodiment, is not particularly limited.

In the present embodiment, as shown in the same figure, the holding members 83 directly hold the top surface 723 of the sub board 72. Further, the bottom surface 721 of the sub board 72 has the first seal member 75 attached to it. The sealed space 731a in the present embodiment is defined by the performance board 50, the sub board 72, the first seal member 75, and the sealing pattern 76, and the sub board 72 is formed with a suction hole 724 which opens to that sealed space 731a.

Note that, in the same way as the first embodiment, in the sub board 72, the position where the first seal member 75 is attached is not particularly limited. For example, as shown in FIG. 18, the first seal member 75 may also be attached in a ring shape along the side face of the sub board 72. Note that, in that figure, illustration of the guide pins and the guide holes is omitted.

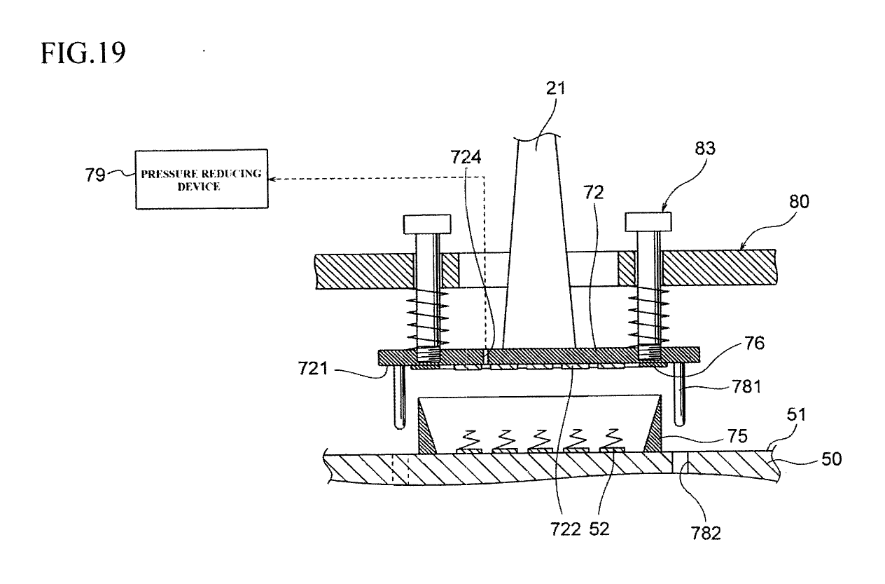

Alternatively, as shown in FIG. 19, the top surface 51 of the performance board 50 may also have the first seal member 75 attached to it. Note that, in this case, the bottom surface 721 of the sub board 72 is provided with the sealing pattern 76.

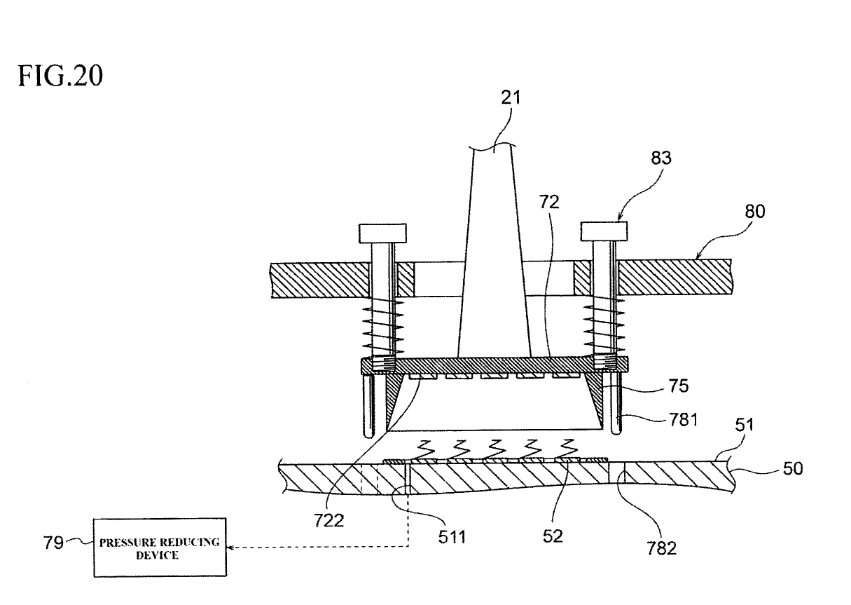

Further, in the present embodiment, the sub board 72 is formed with the suction hole 724, but the invention is not particularly limited to this. As shown in FIG. 20, a suction hole 511 which opens to the sealed space 731 a (see FIG. 17) may also be formed in the performance board 50.

In the present embodiment as well, sliding is not required for the operation for making the sub board 72 approach the performance board 50, so wear between the members and production of dust due to sliding can be suppressed. Due to this, the reliability of the electrical connection between the test head 20 and the performance board 50 can be improved.

Next, a third embodiment will be explained.

### Third Embodiment

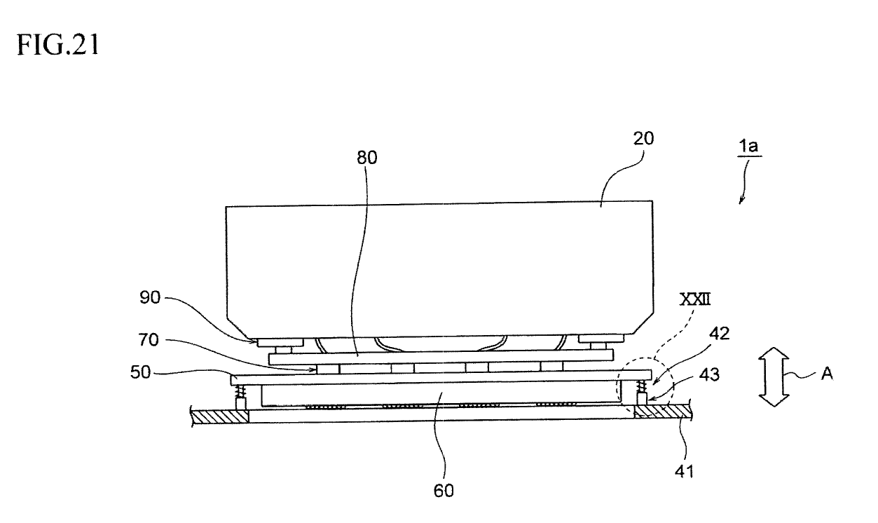

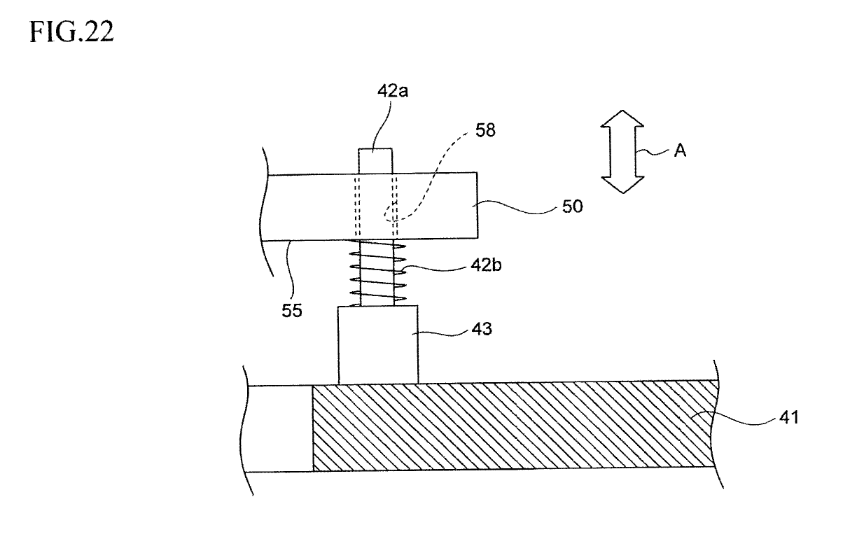

FIG. 21 is a view which shows a semiconductor wafer test apparatus in the present embodiment, while FIG. 22 is an enlarged view of a part XXII of FIG. 21. Note that, FIG. 21 is a view which corresponds to FIG. 1 of the first embodiment. Illustration of the conveyor device is omitted.

The semiconductor wafer test apparatus 1a in the present embodiment, as shown in FIG. 21, differs from the first embodiment on the points of further having: holding members 42 which support the performance board 40 so as to be freely moveable along the contact direction A; and PB moving devices 43 which move the performance board 50 relative to the connecting device 70 along the contact direction A, but the rest of the configuration is similar to the first embodiment. Below, only the points which differ from the first embodiment will be explained. Parts which are configured similar to the first embodiment will be assigned the same reference numerals and explanations will be omitted. Note that, in the present embodiment, the provision or non provision of the Z-axis movement device is not particularly limited.

Each holding member 42, as shown in FIG. 22, has a guide member 42a and spring 42b and supports an outer edge part of the performance board 50. Note that, in the present embodiment, two holding members 42 support the performance board 50, but the number of the holding members 42 is not particularly limited.

The guide member 42a is a pin-shaped member which guides the performance board 50 along the contact direction A and is inserted into a guide through hole 58 which is formed in the performance board 50. Further, this guide member 42a is connected with the PB moving device 43 at its bottom end.

The spring 42b connect the top surface of the PB moving device 43 and the bottom surface 55 of the performance board 50 and supports the performance board 50 to as to be able to free move relative to the PB moving device 43.

Each PB moving device 43 is a device which moves the performance board 50 along the contact direction A through the spring 42b and is arranged on the housing 41 which holds the conveyor device 40 (see FIG. 1). In the present embodiment, two PB moving devices 43 are arranged on the housing 41 so as to correspond to the holding members 42. As specific examples of the PB moving devices 43, air cylinders or other actuators may be illustrated, but the invention is not particularly limited to these.

Next, a connecting method in the present embodiment will be explained.

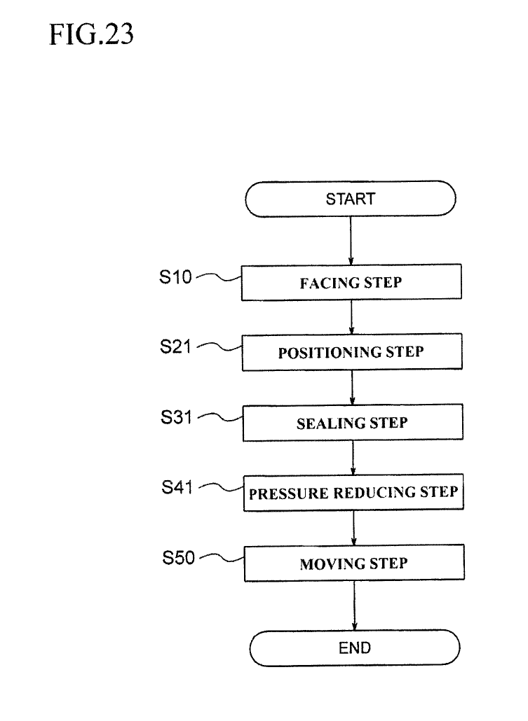

FIG. 23 is a flow chart which shows a connecting method of the third embodiment of the present invention, FIG. 24 is a cross-sectional view which explains a sealing step of FIG. 23, and FIG. 25 is a cross-sectional view which explains a pressure reducing step of FIG. 23.

In the connecting method of the present embodiment, the positioning step S21, the sealing step S31, and the pressure reducing step S41 differ from the first embodiment, but the other steps are similar to the first embodiment. Below, only the points of difference from the first embodiment will be explained. Parts which are similar to the first embodiment will be assigned the same reference numerals and explanations will be omitted. Note that, the provision or non provision of the moving step S50, like in the first embodiment, is not particularly limited.

In the positioning step S21 of the present embodiment, the PB moving devices 43 are used to make the performance board 50 approach the connecting device 70 and make the guide pins 781 be inserted relative to the guide holes 782. Due to this, the sub board 72 is positioned relative to the performance board 50.

Next, in the sealing step S31, as shown in FIG. 24, the PB moving devices 43 are used to make the performance board 50 further approach the connecting device 70 and make the sealing pattern 76 closely contact the front end 751 of the first seal member 75. Due to this, a sealed space 731 which is defined by the performance board 50, the sub board 72, the housing 74, the first seal member 75, the sealing pattern 76, and the second seal member 77 is formed.

Next, in the pressure reducing step S41, as shown in FIG. 25, the pressure reducing device 79 is used to reduce the pressure inside the sealed space 731 through the suction hole 745. At this time, the springs 42b of the holding members 42 extend and the first seal member 75 closely contacts the sealing pattern 76 while deforming whereby the performance board 50 further rises.

Due to the performance board 50 further rising, as shown in the same figure, the sub board 72 and the performance board 50 approach each other, and the PB terminals 52 contact the sub terminals 722 through the contactors 53. Due to this, the test head 20 and the performance board 50 are electrically connected through the connecting device 70, and an IC device which is formed on the semiconductor wafer 100 can be tested.

In the present embodiment as well, sliding is not required for the operation for making the performance board 50 approach the sub board 72, so wear between the members and production of dust due to sliding can be suppressed. Due to this, the reliability of the electrical connection between the test head 20 and the performance board 50 can be improved.

The above explained embodiments were described for facilitating understanding of the present invention and were not explained for limiting the present invention. Therefore, the elements which are disclosed in the above embodiments include all design modifications and equivalents which fall under the technical scope of the present invention.

### REFERENCE SIGNS LIST

1 . . . semiconductor wafer test apparatus
20 . . . test head
50 . . . performance board
52 . . . PB terminal
53 . . . contactor
60 . . . the probe card
70 . . . connecting device
71 . . . connection unit
72 . . . sub board
722 . . . sub terminal
73 . . . sealing mechanism
731,731a . . . sealed space
74 . . . housing
745 . . . suction hole
75 . . . first seal member
76 . . . sealing pattern
77 . . . second seal member
78 . . . positioning mechanism
79 . . . pressure reducing device
80 . . . frame
83 . . . holding member

1. A connecting device which electrically connects a circuit board which has first terminals and a test head, comprising:
a connection board which is electrically connected to the test head and has second terminals which face the first terminals;
a sealing device which forms a sealed space between the connection board and the circuit board; and
a pressure reducing device which reduces the pressure of the sealed space, wherein
the pressure reducing device reduces the pressure of the sealed space so that the circuit board and the connection board approach each other and the first terminals and the second terminals contact.

2. The connecting device as set forth in claim 1, wherein
one of the first terminal or the second terminal has a contactor which can elastically deform along the contact direction of the first terminal and the second terminal.

3. The connecting device as set forth in claim 1, wherein
the sealing device has:
a housing which has an external shape which is larger than the connection board and which is attached to an opposite side surface to a formation surface of the second terminals in the connection board; and
a ring-shaped first seal member which is provided between an outside part and the circuit board, the outside part which is positioned outside from the connection board in the housing.

4. The connecting device as set forth in claim 3, wherein
the sealing device further has a ring-shaped second seal member which is provided between the housing and the connection board.

5. The connecting device as set forth in claim 3, wherein
the first seal member is attached to one of the housing or the circuit board, and
the sealing device further has a ring-shaped conductor pattern which is attached to the other of the circuit board or the housing and closely contacts the first seal member.

6. The connecting device as set forth in claim 5, wherein
the first seal member is attached to the housing, and
the conductor pattern includes a metal interconnect pattern which is provided on the circuit board and is formed simultaneously with the first terminals.

7. The connecting device as set forth in claim 1, wherein
the sealing device has a ring-shaped seal member which is provided between the circuit board and the connection board.

8. The connecting device as set forth in claim 7, wherein
the seal member is attached to one of the circuit board or the connection board, and
the sealing device further comprises a ring-shaped conductor pattern which is provided on the other of the connection board or the circuit board and which closely contacts the seal member.

9. The connecting device as set forth in claim 8, wherein
the seal member is attached to the connection board, and
the conductor pattern includes a metal interconnect pattern which is provided on the circuit board and is formed simultaneously with the first terminals.

10. The connecting device as set forth in claim 1, wherein
one of the circuit board or the connection board has a suction hole which opens to the sealed space, and
the pressure reducing device reduces the pressure of the sealed space through the suction hole.

11. The connecting device as set forth in claim 3, wherein
one of the circuit board, the connection board, or the housing has a suction hole which opens to the sealed space, and
the pressure reducing device reduces the pressure of the sealed space through the suction hole.

12. The connecting device as set forth in claim 1, wherein
the device further comprises a positioning device which positions the connection board relative to the circuit board.

13. The connecting device as set forth in claim 12, wherein
the first terminals and the second terminals are provided inside of the sealed space, and
the positioning device is provided outside of the sealed space.

14. A semiconductor wafer test apparatus comprising:
a test head;
a circuit board which is electrically connected to a probe card; and
a connecting device as set forth in claim 1 which electrically connects the test head and the circuit board, wherein
the connecting device is electrically connected to the test head through a wiring cable.

15. The semiconductor wafer test apparatus as set forth in claim 14, wherein
the circuit board has the first terminals,
the connecting device has a plurality of connection boards which have second terminals which can contact the first terminals, and
the semiconductor wafer test apparatus further comprises a frame having holding members which hold the plurality of connection boards in a freely movable manner along the contact direction of the first terminal and the second terminal.

16. The semiconductor wafer test apparatus as set forth in claim 15, further comprising a moving device which moves the connection boards through a frame relative to the circuit board along a direction substantially parallel to the main surface of the circuit board.

17. A connecting method of electrically connecting a circuit board which has first terminals and a test head, comprising:
making second terminals of a connection board face the first terminals, the connection board which is electrically connected with a test head;
forming a sealed space between the circuit board and the connection board; and
reducing the pressure of the sealed space so that the circuit board and the connection board approach each other and the first terminals and the second terminals contact.

18. The connecting method as set forth in claim 17, further comprising positioning the connection board relative to the circuit board.

19. The connecting method as set forth in claim 17, further comprising moving the connection board relative to the circuit board along a direction substantially parallel to the main surface of the circuit board.
